(19) United States
(12) Patent Application Publication
(10) Pub. No.: US 2026/0182180 A1
(43) Pub. Date: Jun. 25, 2026

(54) Display Device

(71) Applicant: LG Display Co., Ltd., Seoul (KR)

(72) Inventors: Saehoon Oh, Paju-si (KR); JuHan Kim, Paju-si (KR); Youngsung Cho, Paju-si (KR); JiAh Kim, Paju-si (KR)

(21) Appl. No.: 19/314,163

(22) Filed: Aug. 29, 2025

(30) Foreign Application Priority Data
Dec. 24, 2024 (KR) 10-2024-0195933

(51) Int. Cl. H10K 59/131; H10K 59/122; H10K 59/80

(52) U.S. Cl. CPC H10K 59/131; H10K 59/122; H10K 59/80515

(57) ABSTRACT

A display device includes a first pixel electrode in a first subpixel, on a planarization layer, and including first and second edges, a second pixel electrode in a second subpixel, on the planarization layer, spaced from the first pixel electrode, and including a third edge adjacent to the second and fourth edges, a bank respectively on the second and third edges of the first and second pixel electrodes, a first intermediate layer on the first pixel electrode and on a first side surface of the bank, a second intermediate layer on the second pixel electrode and on a second side surface of the bank, an organic layer on the bank and spaced from the first and second intermediate layers, first and second common electrodes respectively on the first and second intermediate layers, and a metal pattern on the organic layer and spaced apart from the first and second common electrodes.

### CROSS REFERENCE TO RELATED APPLICATION

This application claims priority from Republic of Korea Patent Application No. 10-2024-0195933, filed on Dec. 24, 2024 which is hereby incorporated by reference in its entirety.

### TECHNICAL FIELD

The present disclosure relates to an apparatus and particularly to, for example, without limitation, electronic devices, and more specifically, to display devices.

### BACKGROUND

In today's information society, display devices for presenting images or visual information to users are increasingly important. The need for such display devices has caused display technology to be rapidly developed, and various types of display devices, such as a liquid crystal display (LCD) device, an organic light emitting diode (OLED) display device, an inorganic light emitting diode (iLED) display device, a micro light emitting diode (micro LED) display device, a mini light emitting diode (mini LED) displays device, a quantum dot light emitting diode (QLED) display device, and the like, have been developed and used.

These display devices have a structure where a common voltage line for applying a common voltage to a common electrode is disposed in a non-display area. According to this structure, a bezel size of the display devices increases, thus making it difficult to implement a narrow bezel.

### SUMMARY

To address this issue, one or more embodiments of the present disclosure may provide a display device that has a structure where a common voltage line is integrated in a display area, and is capable of reducing a bezel size of a display panel.

One or more embodiments of the present disclosure may provide a display device that includes a structure where a common voltage line and a common electrode contact each other in a display area, and is capable of improving luminance uniformity of a display panel.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can be provided that includes a substrate including a display area where an image is displayed, a planarization layer disposed on the substrate, a first pixel electrode located in an area of a first subpixel among a plurality of subpixels, disposed on the planarization layer, and including a first edge and a second edge, a second pixel electrode located in an area of a second subpixel among the plurality of subpixels, disposed on the planarization layer, spaced from the first pixel electrode, and including a third edge adjacent to the second edge and a fourth edge, a bank disposed on the second edge of the first pixel electrode and the third edge of the second pixel electrode, a common voltage line disposed on the bank and delivering a common voltage, a first intermediate layer disposed on the first pixel electrode and extending along a first side surface of the bank, a second intermediate layer disposed on the second pixel electrode and extending along a second side surface of the bank, an organic layer disposed on the bank and spaced from the first intermediate layer and the second intermediate layer, a first common electrode disposed on the first intermediate layer and electrically connected to one side of the common voltage line, a second common electrode disposed on the second intermediate layer and electrically connected to the other side of the common voltage line, and a metal pattern disposed on the organic layer and spaced apart from the first common electrode and the second common electrode.

According to one or more example embodiments of the present disclosure, a display device can be provided that includes a substrate including a display area where an image is displayed, a plurality of pixel electrodes disposed on the substrate, a common electrode disposed over the plurality of pixel electrodes, a bank disposed in a matrix form and overlapping with areas between the plurality of pixel electrodes, and a common voltage line disposed on the bank and disposed in the matrix form. In one or more aspects, at least a portion of the common electrode may extend on the bank and be electrically connected to the common voltage line.

According to one or more embodiments of the present disclosure, a display device may be provided that is capable of reducing a bezel size of a display panel and thereby providing an aesthetically satisfying design by including a structure where a common voltage line is integrated in a display area.

According to one or more embodiments of the present disclosure, a display device may be provided that is capable of improving luminance uniformity of a display panel by including a structure where a common voltage line and a common electrode contact each other in a display area.

According to one or more embodiments of the present disclosure, a display device may be provided that is capable of enabling process optimization by including a structure where a common voltage line and a common electrode contact each other by adjusting an angle of the bank without a separate additional process.

Effects or advantages from aspects, examples, and embodiments described herein are not limited thereto, and additional effects or advantages will become apparent to those skilled in the art from the following description.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates a perspective view of an example display device according to embodiments of the present disclosure;

FIG. 2 illustrates an example structure where a touch screen panel is integrated into a display panel in the display device according to embodiments of the present disclosure;

FIG. 3 is an example planar structure of the display panel according to embodiments of the present disclosure;

FIG. 4 illustrates an example cross-sectional structure of the display panel according to embodiments of the present disclosure;

FIG. 5 illustrates an example structure of a display area according to embodiments of the present disclosure;

FIG. 6 is an example plan view of the display device according to embodiments of the present disclosure; and

FIGS. 7 to 11 are example cross-sectional views taken along line X-X′ of FIG. 6 according to embodiments of the present disclosure.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “contact”, “overlap with”, or the like each other via a fourth element. Here, the second element may be included in at least one of two or more elements that “are connected or coupled to”, “contact”, “overlap with”, or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can”.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

Any implementation described herein as an “example” is not necessarily to be construed as preferred or advantageous over other implementations.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Features of various embodiments of the present disclosure may be partially or overall coupled to or combined with each other, and may be variously inter-operated with each other and driven technically as those skilled in the art can sufficiently understand. Embodiments of the present disclosure may be carried out independently from each other, or may be carried out together in co-dependent relationship.

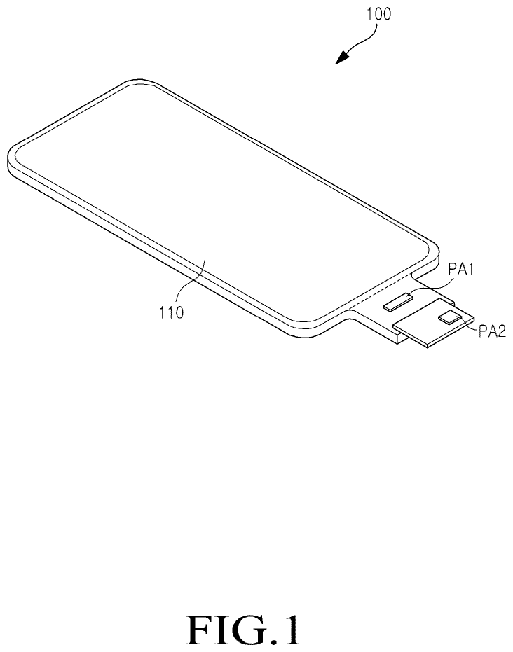

FIG. 1 is a perspective view of an example display device 100 according to embodiments of the present disclosure.

Referring to FIG. 1, in one or more example embodiments, the display device 100 may be applied to portable electronic devices such as a mobile phone, a smart phone, a tablet personal computer, a mobile communication terminal, an electronic notebook, an electronic book, a portable multimedia player (PMP), a navigation device, an ultra-mobile PC (UMPC), and the like.

In one or more embodiments, the display device 100 may be applied to a television, a laptop, a monitor, a billboard, and a wearable device such as a smart watch, a watch phone, and the like. In one or more aspects, the display device 100 may be applied to a dashboard of a vehicle, a center fascia of a vehicle, a center information display (CID) placed in a dashboard of a vehicle, a room mirror display replacing a side mirror of a vehicle, a display placed on the back of a front seat as entertainment for rear seats of a vehicle, and the like.

In one or more embodiments, the display device 100 may be a display device such as an organic light emitting display device using an organic light emitting diode, a quantum dot light emitting display device including a quantum dot light emitting layer, an inorganic light emitting display device including an inorganic semiconductor, a micro light emitting display device using a micro light emitting diode (micro LED), and the like. Hereinafter, discussions are provided based on examples where the display device 100 is an organic light emitting display device, but aspects of the present disclosure are not limited thereto.

Referring to FIG. 1, in one or more embodiments, the display device 100 may include a display panel 110 and at least one display driving circuit as components for displaying an image. The at least one display driving circuit may be one or more circuits for driving the display panel 110. The at least one display driving circuit may include a data driving circuit, a gate driving circuit, a controller, and the like, but aspects of the present disclosure are not limited thereto.

In one or more embodiments, the display device 100 may include the display panel 110, a first pad area PA1, and a second pad area PA2.

The display panel 110 may be in the form of a planar surface in a rectangular shape having a short side in a first direction and a long side in a second direction intersecting the first direction. Corners where the short side in the first direction and the long side in the second direction meet may be formed in a round shape having a predetermined curvature or at a right angle. The planar surface of the display panel 110 is not limited to the rectangular shape, and may be formed into other polygonal shapes, or a circular or oval shape. The display panel 110 may be flat, but aspects of the present disclosure are not limited thereto. For example, the display panel 110 may include a curved portion formed at left and right ends and having a constant curvature or a varying curvature. In one or more aspects, the display panel 110 may be formed flexibly, for example allowing the display panel 110 to be bent, curved, folded, or rolled. However, embodiments of the present disclosure are not limited thereto.

The pad areas (PA1 and PA2) of the display panel 110 may be areas where various circuit elements or configurations are connected. For example, the first pad area PA1 may be an area where a driving circuit (e.g., a data driving circuit and/or a touch driving circuit) is bonded or connected. The second pad area PA2 may be an area where a printed circuit board is connected. Several electronic components such as a timing controller, a touch controller, and the like may be mounted on the printed circuit board.

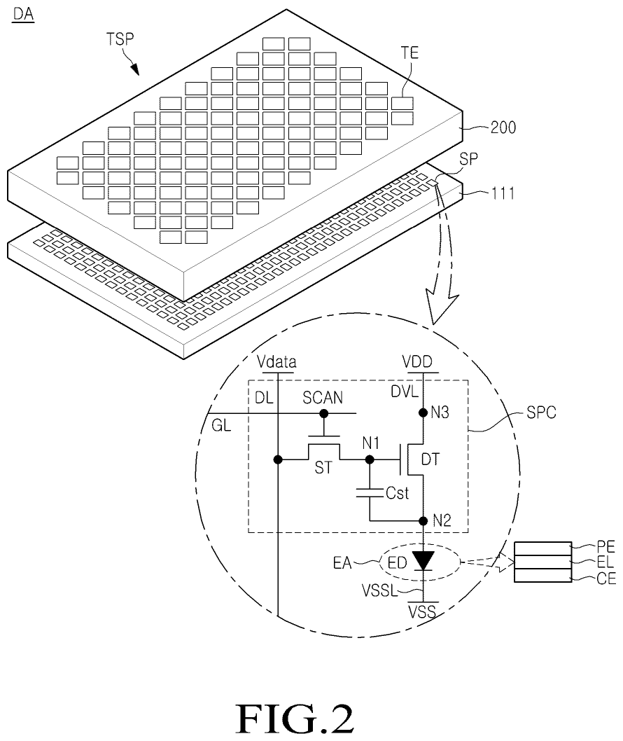

FIG. 2 illustrates an example structure where a touch screen panel is integrated into a display panel 110 in the display device 100 according to aspects of the present disclosure.

Referring to FIG. 2, in one or more example embodiments, the display panel 110 may include a substrate 111 on which a plurality of subpixels SP are disposed, and an encapsulation layer 200 on the substrate 111. The encapsulation layer 200 may be referred to as an encapsulation substrate or an encapsulation part.

In one or more embodiments, the display device 100 may be a self-emissive display device including self-emissive light emitting elements, each of which emits light by itself, but aspects of the present disclosure are not limited thereto. In the example where the display device 100 is a self-emissive display device, each of the plurality of subpixels SP disposed on the substrate 111 may include a light emitting element ED and a subpixel circuit SPC for driving the light emitting element ED.

The subpixel circuit SPC may include a plurality of transistors and at least one capacitor for driving the light emitting element ED, but embodiments of the present disclosure are not limited thereto. In one or more embodiments, the subpixel circuit SPC can drive the light emitting element ED by supplying a driving current to the light emitting element ED at a predefined timing. The light emitting element ED can emit light by being driven by the driving current.

Several types of signal lines for driving a plurality of subpixels SP may be disposed on the substrate 111 of the display panel 110. For example, the several types of signal lines may include a plurality of data lines DL for delivering data signals (which may be referred to as data voltages or image signals) to a plurality of subpixels SP, a plurality of gate lines GL for delivering gate signals (which may be referred to as scan signals) to the plurality of subpixels SP, and the like.

For example, the plurality of data lines DL and the plurality of gate lines GL may intersect each other. Each of the plurality of gate lines GL may extend in a first direction (e.g., a row or column direction). Each of the plurality of data lines DL may extend in a second direction (e.g., the column or row direction) different from the first direction.

For example, the first direction may be the row direction, and the second direction may be the column direction. In another example, the first direction may be the column direction, and the second direction may be the row direction. Herein, the row direction and the column direction may not absolute directions, but relative directions. For example, the column direction may be the row direction and the row direction may be the column direction depending on a direction at which the display device 100 or the display panel 110 is viewed. Hereinafter, for convenience of explanation, discussions may be provided based on examples where each of a plurality of data lines DL is disposed in the column direction, and each of a plurality of gate lines GL is disposed in the row direction, but aspects of the present disclosure are limited thereto. Herein, an angle between the first direction and the second direction may be vertical (or 90 degrees) or an angle different from the vertical.

The data driving circuit may be a circuit for driving a plurality of data lines DL and can output data signals to the plurality of data lines DL.

The data driving circuit can receive image data DATA in digital form from the controller, convert the received image data DATA into data signals in analog form, and output the resulting data signals to the plurality of data lines DL.

For example, the data driving circuit may be connected to the display panel 110 by a tape-automated-bonding (TAB) technique, or connected to a conductive pad such as a bonding pad of the display panel 110 by a chip-on-glass (COG) technique or a chip-on-panel (COP) technique, or connected to the display panel 110 by a chip-on-film (COF) technique. However, aspects of the present disclosure are not limited thereto.

In one or more embodiments, the data driving circuit may be located in, and/or electrically connected to, but not limited to, one side or edge (e.g., an upper portion or a lower portion) of the display panel 110. In one or more embodiments, the data driving circuit may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit may be connected to an area located outside of the display area DA of the display panel 110 or be disposed in the display area DA of the display panel 110.

The gate driving circuit may be a circuit for driving a plurality of gate lines GL and can supply gate signals to the plurality of gate lines GL.

The gate driving circuit can receive several types of gate driving control signals GCS, and a first gate voltage corresponding to a turn-on voltage (or a turn-on level voltage) and a second gate voltage corresponding to a turn-off voltage (or a turn-off level voltage). Thereby, the gate driving circuit can generate a gate signal including a period with the first gate voltage and a period with the second gate voltage during a certain period of time (e.g., a period of one frame time or a sub-period of the period of one frame time), and supply the generated gate signals to the plurality of gate lines GL. For example, the turn-on level voltage may be a high level voltage and the turn-off level voltage may be a low level voltage. In another example, the turn-on level voltage may be a low level voltage and the turn-off level voltage may be a high level voltage.

In one or more embodiments, the gate driving circuit included in the display device 100 may be embedded into the display panel 110 by a gate-in-panel (GIP) technique, but aspects of the present disclosure are not limited thereto. In an example where the gate driving circuit is implemented by the gate-in-panel (GIP) technique, the gate driving circuit may be disposed on the substrate 111 of the display panel 110 during the process of manufacturing the display panel 110 or display device 100. Herein, the gate driving circuit embedded in the display panel 110 by the gate-in-panel (GIP) technique may also be referred to as a “gate-in-panel circuit.”

For example, the gate driving circuit may be disposed in the non-display area NDA of the display panel 110. In another example, the gate driving circuit may be disposed in the display area DA of the display panel 110. In one or more embodiments, the gate driving circuit may be disposed in, and/or electrically connected to, but not limited to, a first partial area (e.g., a left portion or a right portion) in the display area DA of the display panel 110. In one or more aspects, the gate driving circuit may be disposed in, and/or electrically connected to, but not limited to, a first partial area (e.g., a left portion or a right portion) in the display area DA, and a second partial area (e.g., the right portion or the left portion) in the display area DA. In one or more aspects, the gate driving circuit may be disposed in all or one or more of areas of the display area DA.

In an example where the gate driving circuit is disposed in the display area DA of the display panel 110, the gate driving circuit may vertically overlap with one or more subpixels SP disposed in the display area DA. For example, the gate driving circuit may vertically overlap with one or more light emitting elements and one or more transistors included in one or more subpixels SP disposed in the display area DA. The gate driving circuit may vertically overlap with the plurality of light emitting elements and a plurality of transistors included in a plurality of subpixels SP disposed in the display area DA. The gate driving circuit may include a plurality of transistors. Each of the plurality of transistors included in the gate driving circuit may include an active layer including a first semiconductor material, and each of the plurality of transistors included in the subpixels SP may include an active layer including a second semiconductor material. For example, the first semiconductor material and the second semiconductor material may be substantially the same as each other. In another example, the first semiconductor material and the second semiconductor material may be different from each other. For example, the first semiconductor material may be a silicon-based semiconductor material (e.g., a low temperature poly silicone (LTPS)), and the second semiconductor material may be an oxide semiconductor material. For example, the active layer may be a semiconductor layer, but aspects of the present disclosure are not limited thereto.

The controller may be a device for controlling the data driving circuit and the gate driving circuit, and can control driving timing for a plurality of data lines DL and driving timing for a plurality of gate lines GL.

The controller can supply a data control signal DCS to the data driving circuit to control the data driving circuit, and supply a gate control signal GCS to the gate driving circuit to control the gate driving circuit.

The controller can receive image data input from a host system and supply image data DATA readable by the data driving circuit based on the input image data to the data driving circuit.

The controller may be implemented in a separate component from the data driving circuit, or integrated with the data driving circuit, so that the controller and the data driving circuit can be implemented in a single integrated circuit.

The controller may be a timing controller used in the typical display technology or a control apparatus/device capable of additionally performing other control functionalities in addition to the typical function of the timing controller. In one or more embodiments, the controller may be one or more other control circuits different from the timing controller, or a circuit or component in the control apparatus/device. The controller may be implemented using various circuits or electronic components such as an integrated circuit (IC), a field programmable gate array (FPGA), an application specific integrated circuit (ASIC), a processor, and/or the like. However, embodiments of the present disclosure are not limited thereto.

The controller may be mounted on a printed circuit board, a flexible printed circuit, or the like, and may be electrically connected to the data driving circuit and the gate driving circuit through the printed circuit board, the flexible printed circuit, and/or the like.

The controller can transmit signals to, and receive signals from, the data driving circuit via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

The plurality of transistors may include a driving transistor DT for driving the light emitting element ED and a scan transistor ST configured to be turned on or off by a scan signal SCAN.

The driving transistor DT can supply a driving current to the light emitting element ED. The scan transistor ST may be configured to control an electrical state of a corresponding node in the subpixel circuit SPC or to control the state or operation of the driving transistor DT. The at least one capacitor may include a storage capacitor Cst configured to maintain a voltage at a constant level during a display frame or a certain period of the display frame.

To drive one or more subpixels SP, at least one data signal Vdata, which is an image signal, and at least one scan signal SCAN, which is a gate signal, may be applied to the one or more subpixels SP. Further, to drive one or more subpixels SP, common driving signals including a driving voltage VDD and a base voltage VSS may be supplied to the one or more subpixels SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed for each subpixel SP, and the common electrode CE may be an electrode commonly disposed in all or some of a plurality of subpixels SP. For example, the pixel electrode PE may be an anode, and the common electrode CE may be a cathode. In another example, the pixel electrode PE may be a cathode, and the common electrode CE may be an anode. Hereinafter, for convenience of explanation, discussions may be provided based on examples where the pixel electrode PE is an anode, and the common electrode CE is a cathode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

The emission layer EML may be disposed for each subpixel SP, or be commonly disposed across all or some of a plurality of subpixels SP. The common intermediate layer EL_COM may be commonly disposed across all or some of a plurality of subpixels SP, but aspects of the present disclosure are not limited thereto.

The emission layer EML may be disposed for each light emitting area or be commonly disposed across all or some of a plurality of light emitting areas. The common intermediate layer EL_COM may be commonly disposed across all or some of a plurality of light emitting areas and a non-light emitting area, but aspects of the present disclosure are not limited thereto.

For example, the first common intermediate layer COM1 may include a opening injection layer (HIL), an electron blocking layer (EBL), a opening transfer layer (HTL), and the like, but aspects of the present disclosure are not limited thereto. The second common intermediate layer COM2 may include an electron transfer layer (ETL), a opening blocking layer (HBL), an electron injection layer (EIL), and the like, but aspects of the present disclosure are not limited thereto.

The opening injection layer can inject openings from the pixel electrode PE to the opening transport layer, the opening transport layer can transport openings to the emission layer EML, the electron injection layer can inject electrons from the common electrode CE to the electron transport layer, and the electron transport layer can transport electrons to the emission layer EML.

For example, the common electrode CE may be electrically connected to a base voltage line VSSL. A base voltage VSS, which is a type of common voltage, may be applied to the common electrode CE through the base voltage line VSSL. The pixel electrode PE may be electrically connected directly or indirectly (via another transistor) to a second node N2 of the corresponding driving transistor DT of each subpixel SP. Herein, the base voltage VSS may also be referred to as a first common voltage, a low power supply voltage, or a low voltage, and the base voltage line VSSL may also be referred to as a first common voltage line, a low power supply voltage line, or a low voltage line.

Each light emitting element ED may be configured by overlapping of a pixel electrode PE, an emission layer EML in an intermediate layer EL, and a common electrode CE. A respective light emitting area may be formed by each light emitting element ED. For example, a respective light emitting area of each light emitting element ED may include an area where a pixel electrode PE, an emission layer EML in an intermediate layer EL, and a common electrode CE overlap with each other.

In one or more embodiments, each, or one or more, of light emitting elements ED included in the display panel 110 may be an organic light emitting diode (OLED), an inorganic light emitting diode (LED), a quantum dot light emitting element, a micro LED, or a mini LED, but aspects of the present disclosure are not limited thereto. In the example where each light emitting element ED is an organic light emitting diode (OLED), the corresponding intermediate layer EL of each light emitting element ED may be a layer including an organic material.

Referring to FIG. 2, the driving transistor DT may be a transistor configured to supply a driving current to the light emitting element ED. The driving transistor DT may be connected between a driving voltage line DVL and the light emitting element ED.

The driving transistor DT may include a first node N1, a second node N2, and a third node N3. The second node N2 may be electrically connected to the light emitting element ED. A data signal VDATA may be applied to the first node N1. A driving voltage VDD, which is a type of common voltage, delivered through the driving voltage line DVL may be applied to the third node N3. The driving transistor DT may be connected to the second node N2 and the third node N3. Herein, the driving voltage VDD may also be referred to as a second common voltage, a high power supply voltage, or a high voltage, and the driving voltage line DVL may also be referred to as a second common voltage line, a high power supply voltage line, or a high voltage line.

In the driving transistor DT, the first node N1 may be a gate node, the second node N2 may be a source node or a drain node, and the third node N3 may be the drain node or the source node. Hereinafter, for merely convenience of explanation, discussions may be provided based on examples where the first, second, and third nodes (N1, N2, and N3) of the driving transistor DT are gate, source, and drain nodes, respectively. However, embodiments of the present disclosure are not limited thereto.

The scan transistor ST included in the subpixel circuit SPC illustrated in FIG. 2 may be a switching transistor for transferring a data signal Vdata, which is an image signal, to the first node N1, which is the gate node of the driving transistor DT.

The scan transistor ST can be turned on or turned off by a scan signal SCAN, which is a type of gate signal, applied through a scan line SCL, which is a type of gate line GL, and control an electrical connection between the first node N1 of the driving transistor DT and a data line DL. The drain electrode or source electrode of the scan transistor ST may be electrically connected to the data line DL. The source electrode or drain electrode of the scan transistor ST may be electrically connected to the first node N1 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include at least one capacitor electrode electrically connected to the second node N2 of the driving transistor DT or corresponding to the second node N2 of the driving transistor DT, and at least one capacitor electrode electrically connected to the first node N1 of the driving transistor DT or corresponding to the first node N1 of the driving transistor DT.

The storage capacitor Cst may be an external capacitor intentionally designed to be located outside of the driving transistor DT, and therefore, be different from an internal capacitor such as a parasitic capacitor (e.g., a Cgs, a Cgd) that may be formed between the first node N1 and the second node N2 of the driving transistor DT. However, aspects of the present disclosure are not limited thereto.

Each of the driving transistor DT and the scan transistor ST may be an n-type transistor or a p-type transistor, but embodiments of the present disclosure are not limited thereto. For example, one of the driving transistor DT and the scan transistor ST may be one of an n-type transistor and a p-type transistor.

The display panel 110 may have a top emission structure or a bottom emission structure. In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase. In an example where the display panel 110 has the bottom emission structure, the subpixel circuit SPC may not overlap with the light emitting element ED in the vertical direction.

As shown in FIG. 2, the subpixel circuit SPC may include two transistors (2T: DT and ST) and one capacitor (1C: Cst) (which may be referred to as a “2T1C structure”), and in some implementations, may further include one or more transistors, and/or further include one or more capacitors.

For example, the subpixel circuit SPC may have a 3T1C structure including 3 transistors and 1 capacitor. In another example, the subpixel circuit SPC may have an 8T1C structure including 8 transistors and 1 capacitor. In another example, the subpixel circuit SPC may have a 6T2C structure including 6 transistors and 2 capacitors. In another example, the subpixel circuit SPC may have a 7T1C structure including 7 transistors and 1 capacitor. However, embodiments of the present disclosure are not limited thereto.

The types and number of gate signals supplied to a subpixel SP, and/or the types and number of gate lines connected to the subpixel SP may vary depending on a structure of a corresponding subpixel circuit SPC. Further, the types and number of common driving signals supplied to a subpixel SP may vary depending on a structure of a corresponding subpixel circuit SPC.

Referring to FIG. 2, since circuit elements (e.g., light emitting elements ED such as organic light emitting diodes (OLED) including an organic material) in each subpixel SP are vulnerable to external moisture or oxygen, an encapsulation layer 200 may be disposed in the display panel 110. The encapsulation layer 200 can prevent or reduce external moisture or oxygen from penetrating into the circuit elements (e.g., the light emitting elements ED). The encapsulation layer 200 may be disposed in various shapes or configurations to prevent or reduce light emitting elements ED from contacting moisture or oxygen. For example, the encapsulation layer 200 may include two or more layers in which one or more organic layers and one or more inorganic layers are alternately stacked, but aspects of the present disclosure are not limited thereto.

Referring to FIG. 2, in one or more embodiments, to provide a touch sensing function, a touch screen panel TSP may be embedded in the display panel 110 and be formed on the encapsulation layer 200. For example, in the display device 100, a plurality of touch electrodes TE included in the touch screen panel TSP may be disposed on the encapsulation layer 200 of the display panel 110.

In one or more embodiments, the display device 100 can provide not only a function of displaying an image, but also a touch sensing function of detecting whether a touch is applied by a touch object such as a finger or pen or detecting a touch location.

For example, when the encapsulation layer 200 includes a plurality layers, touch electrodes TE may be disposed between a first encapsulation layer and a second encapsulation layer, but aspects of the present disclosure are not limited thereto.

The display device 100 can perform touch sensing by a capacitance-based touch sensing technique such as a self-capacitance touch sensing technique or a mutual-capacitance touch sensing technique.

In an example where the mutual-capacitance-based touch sensing technique is implemented in the display device 100, a plurality of touch electrodes TE may be classified into touch driving electrodes to which touch driving signals are applied through touch driving lines, and touch sensing electrodes configured to sense touch sensing signals through touch sensing lines and forming capacitances with the touch driving electrodes. Both the touch driving lines and the touch sensing lines may be referred to as touch lines, and both the touch driving signals and the touch sensing signals may be referred to as touch signals.

In one or more embodiments, an area of each touch driving electrode to which a touch driving signal is applied and an area of each touch sensing electrode from which a touch sensing signal is transmitted may be the same as or different from each other.

For example, when it is desired to relatively reduce a parasitic capacitance by a touch sensing electrode from which a touch sensing signal is transmitted, an area of the touch sensing electrode may be formed smaller than an area of a touch driving electrode. In this implementation, the area of the touch driving electrode to which the touch driving signal is applied and the area of the touch sensing electrode from which the touch sensing signal is transmitted may be formed at a ratio of 5:1 to 2:1. For example, the area of the touch driving electrode and the area of the touch sensing electrode may be formed at a ratio of 4:1, but aspects of the present disclosure are not limited thereto.

In the mutual-capacitance-based touch sensing technique, when a touch is applied by a touch object such as a finger, a pen, or the like, the presence or absence of the touch and a location of the touch (or touch coordinates) can be detected based on a change in mutual capacitance formed between the touch driving electrode and the touch sensing electrode.

In an example where the self-capacitance-based touch sensing technique is implemented in the display device 100, each touch electrode TE may serve as both a touch driving electrode and a touch sensing electrode. In this implementation, a touch driving signal may be applied to at least one touch electrode TE through one touch line, and a touch sensing signal transmitted from the at least one touch electrode TE to which the touch driving signal is applied may be received through the same touch line. Therefore, in the self-capacitance-based touch sensing technique, there is no distinction between the touch driving electrode and the touch sensing electrode, and between the touch driving line and the touch sensing line.

In the self-capacitance-based touch sensing technique, when a touch is applied by a touch object such as a finger, a pen, or the like, the presence or absence of the touch and a location of the touch (or touch coordinates) can be detected based on a change in capacitance formed between the touch object and at least one touch electrode TE.

According to these configurations, the display device 100 may sense a touch by the mutual-capacitance-based touch sensing technique or may sense a touch by the self-capacitance-based touch sensing technique.

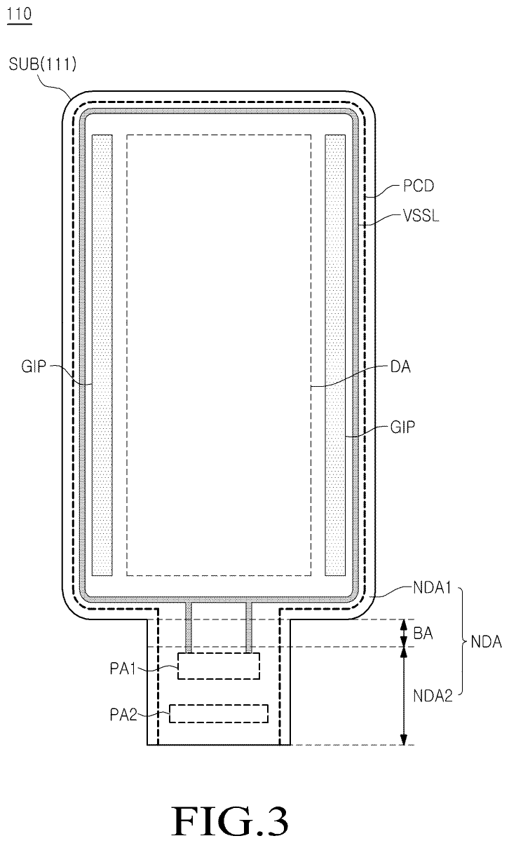

FIG. 3 is an example planar structure of the display panel 110 according to aspects of the present disclosure.

Referring to FIG. 3, in one or more example embodiments, a substrate 111 of the display panel 110 may include a display area DA and a non-display area NDA. The display area DA and the non-display area NDA may be areas defined in the display panel 110.

For example, one or more lines, one or more electrodes, and the like may be disposed on the substrate 111. In one or more aspects, the substrate 111 included in the display panel 110 may be a flexible substrate that can be bent or folded in a certain range of angles. Herein, “bending or bent”, “folding or folded”, or “flexible” may have the same meaning as each other.

The non-display area NDA may be an area where an image is not displayed, and be an area except for the display area DA. Subpixels SP may not be disposed in the non-display area NDA. In one or more aspects, at least one dummy subpixel, which is not directly involved in image displaying, may be disposed in the non-display area NDA.

In one or more embodiments, the non-display area NDA may include a first non-display area NDA, a bending area BA, and a second non-display area NDA2.

The first non-display area NDA1 may be located outside of the display area DA, and be an area closest to the display area DA among the first non-display area NDA1, the bending area BA, and the second non-display area NDA2.

The second non-display area NDA2 may include a pad area allowing several pads to be disposed and including, for example, a first pad area PA1 and a second pad area PA2. For example, the pad area may be located farthest away from the display area DA among the first non-display area NDA1, the bending area BA, and the second non-display area NDA2.

The bending area BA may be an area allowing the substrate 111 to be bent or folded and may be located between the first non-display area NDA1 and the second non-display area NDA2.

The substrate 111 may include the display area DA where an image is displayed and the non-display area NDA located outside of the display area DA. A plurality of subpixels SP may be disposed in the display area DA. In one or more aspects, the non-display area NDA may include a gate-in-panel (GIP) area where a gate driving circuit implemented by a gate-in-panel (GIP) technique is disposed, the bending area BA where a plurality of lines run, and the second non-display area NDA2 where a data driving circuit is electrically connected, and the like.

For example, the gate-in-panel (GIP) area may be located in an area adjacent to, or contacting, a left outer edge of the display area DA and/or an area adjacent to, or contacting, a right outer area thereof. In one or more aspects, the non-display area NDA may include an upper non-display area adjacent to, or contacting, an upper outer edge of the display area DA and a lower non-display area adjacent to, or contacting, a lower outer edge thereof. The second non-display area NDA2 may be an area farther away from the display area DA than the bending area BA, and may include the pad area (e.g., including the first pad area PA1 and the second pad area PA2) to which at least one circuit component such as a printed circuit board is electrically connected.

As described above, the substrate (SUB, 111) may include the bending area BA, which can be bent or folded, and when being bent or folded, the bending area BA may be located on the lower surface of a portion of the substrate 111 that is not bent or folded. The bending area BA may be a portion of the non-display area NDA, and be located between a driving circuit area to which a data driving circuit is electrically connected and the display area DA.

According to the subpixel structure of FIG. 2, to drive at least one subpixel SP, at least one driving voltage line DVL for delivering a driving voltage VDD to the at least one subpixel SP, at least one base voltage line VSSL for delivering a base voltage VSS to a common electrode CE of a corresponding light emitting element ED of the at least one subpixel SP, and the like may be further disposed on the substrate (SUB, 111).

Referring to FIG. 3, for example, a plurality of driving voltage lines DVL may be disposed in a column direction, but embodiments of the present disclosure are not limited thereto. To efficiently deliver a driving voltage VDD through the plurality of driving voltage lines DVL, driving voltage patterns, which are integrally formed as a single unit with, or electrically connected to, the plurality of driving voltage lines DVL, respectively, may be disposed in the non-display area NDA.

The plurality of driving voltage lines DVL may electrically interconnect, through the driving voltage patterns, the bending area BA and a data driving circuit or a printed circuit board connected to the pad area (e.g., the first pad area PA1 and/or the second pad area PA2). The pad area (PA1 and/or PA2) may be an area where various circuit configurations are connected. For example, the first pad area PA1 may be an area where a driving circuit (e.g., a data driving circuit and/or a touch driving circuit) is bonded or connected. The second pad area PA2 may be an area where a printed circuit board is connected. Several electronic components such as a timing controller, a touch controller, and the like may be mounted on the printed circuit board.

To efficiently deliver the base voltage VSS, for example, one or more base voltage lines VSSL may be disposed in the non-display area NDA such that the one or more base voltage lines VSSL surround an outer edge of the display area DA. In one or more aspects, the one or more base voltage lines VSSL may pass through the bending area BA and be electrically connected to a data driving circuit or a printed circuit board connected to a driving circuit area.

A crack prevention pattern PCD may be disposed on the substrate (SUB, 111). The crack prevention pattern PCD may be disposed in a portion of the non-display area NDA located further outwardly from the display area DA than the one or more base voltage lines VSSL, but aspects of the present disclosure are not limited thereto.

For example, the crack prevention pattern PCD may be a pattern for preventing or reducing of lines running on the substrate (SUB, 111) from being cracked. In one or more aspects, the crack prevention pattern PCD may be disposed in a zigzag pattern, but aspects of the present disclosure are not limited thereto.

For example, one or more signal lines among signal lines passing through the bend area BA may be cracked (e.g., electrically disconnected) or form a short circuit with adjacent one or more signal lines when the bending area BA is bent. In this case, since signals cannot be delivered accurately through the cracked (e.g., electrically disconnected) lines or the short-circuited signal lines, display driving may not be normally performed, which may hinder proper image display and significantly deteriorate image quality. To address these issues, one or more crack prevention patterns PCD may be disposed in the display panel 110. It should be noted that configurations of crack prevention patterns PCD according to embodiments of the present disclosure are not limited thereto.

As described above, the display panel 110 may use a flexible substrate (SUB, 111) and allow the bending area BA to which a data drive circuit is connected to be bent. In this configuration, when the bending area BA is bent, a portion of the substrate 111 can be folded backwardly or forwardly in a certain range of angles. The folded portion of the bending area BA may be a portion in which an image is not displayed and be invisible in front of the display panel 110.

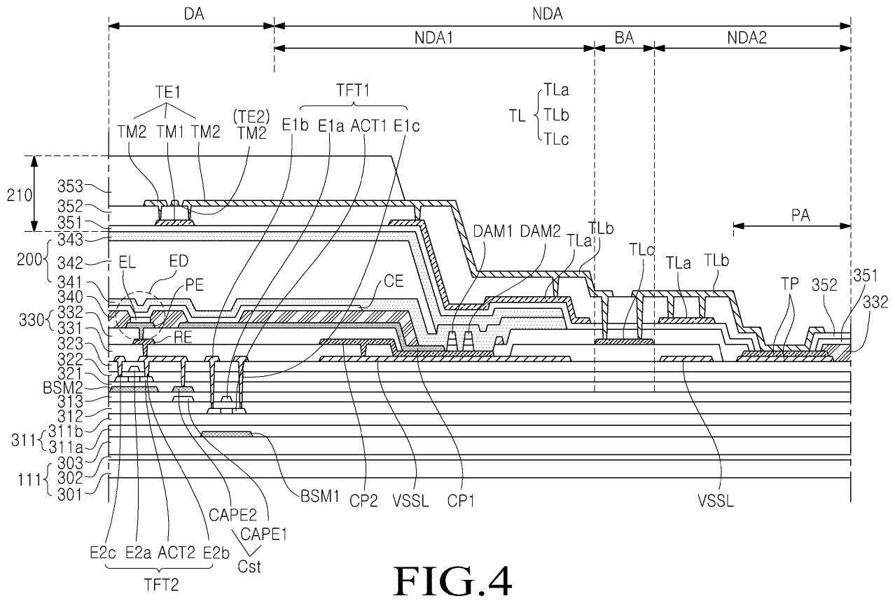

FIG. 4 illustrates an example cross-sectional structure of the display panel 110 according to embodiments of the present disclosure.

Referring to FIG. 4, in one or more example embodiments, the display panel 110 may include a substrate 111, a transistor part, a light emitting element part, and an encapsulation part, but aspects of the present disclosure are not limited thereto.

The substrate 111 may be in the form of a single layer or multilayer. In an example where the substrate 111 includes a multilayer, the substrate 111 may include a first substrate 301, an intermediate substrate layer 302, and a second substrate 303. The intermediate substrate layer 302 may be located between the first substrate 301 and the second substrate 303. In one or more aspects, each of the first substrate 301 and the second substrate 303 may be a polyimide (PI) layer, but aspects of the present disclosure are not limited thereto. The intermediate substrate layer 302 may be an inorganic insulating layer, but aspects of the present disclosure are not limited thereto. When electric charges are stored on the first substrate 301, which is a polyimide (PI) layer, the intermediate substrate layer 302 can block the charges from affecting transistors disposed on the second substrate 303 through the second substrate 303, which is a polyimide (PI) layer.

Further, the intermediate substrate layer 302 can block moisture from moving upwardly through the first substrate 301. For example, the intermediate substrate layer 302 may be in the form of a single layer of silicon nitride (SiNx) or silicon oxide (SiOx) or a multilayer of silicon nitride (SiNx) and/or silicon oxide (SiOx), or be in the form of double layers of silicon dioxide (SiO2) and silicon nitride (SiNx), but aspects of the present disclosure are not limited thereto.

The transistor part may include insulating layers (311, 312, 313, 321, 322, and 323), thin film transistors (TFT1 and TFT2), a storage capacitor Cst, and several electrodes or signal lines, on the substrate 111.

The thin film transistors (TFT1 and TFT2) included in the transistor part may include a first thin film transistor TFT1 and a second thin film transistor TFT2.

The first thin film transistor TFT1 may include a first active layer ACT1, a first electrode E1a, a second electrode E1b, and a third electrode E1c.

The first electrode E1a may be a gate electrode, the second electrode E1b may be a source electrode or a drain electrode, and the third electrode E1c may be the drain electrode or the source electrode. Hereinafter, for convenience of explanation, discussions may be provided based on examples where the first, second, and third electrodes (E1a, E1b, and E1c) are a first gate electrode E1a, a first source electrode E1b, and a first drain electrode E1c, respectively. However, aspects of the present disclosure are not limited thereto.

The first active layer ACT1 may include a first semiconductor material. For example, the first semiconductor material may include an oxide semiconductor, amorphous silicon, polysilicon, low-temperature polysilicon (LTPS), or the like, but embodiments of the present disclosure are not limited thereto. The first thin film transistor TFT1 may be a p-channel transistor or an n-channel transistor, but aspects of the present disclosure are not limited thereto.

The second thin film transistor TFT2 may include a second active layer ACT2, a fourth electrode E2a, a fifth electrode E2b, and a sixth electrode E2c.

The fourth electrode E2a may be a gate electrode, the fifth electrode E2b may be a source electrode or a drain electrode, and the sixth electrode E2c may be the drain electrode or the source electrode. Hereinafter, for convenience of explanation, discussions may be provided based on examples where the fourth, fifth, and sixth electrodes (E2a, E2b, and E2c) are a second gate electrode E2a, a second source electrode E2b, and a second drain electrode E2c, respectively. However, embodiments of the present disclosure are not limited thereto.

The second active layer ACT2 may include a second semiconductor material. For example, the second semiconductor material may include an oxide semiconductor, amorphous silicon, polysilicon, or low-temperature polysilicon (LTPS), or the like. The second thin film transistor TFT2 may be a p-channel transistor or an n-channel transistor, but aspects of the present disclosure are not limited thereto.

The types of respective semiconductor materials of the first active layer ACT1 of the first thin film transistor TFT1 and the second active layer ACT2 of the second thin film transistor TFT2 may be as follows.

For example, each of the first active layer ACT1 of the first thin film transistor TFT1 and the second active layer ACT2 of the second thin film transistor TFT2 may include an oxide semiconductor material. For example, each of the first active layer ACT1 of the first thin film transistor TFT1 and the second active layer ACT2 of the second thin film transistor TFT2 may include a low-temperature polysilicon semiconductor material. For example, the first active layer ACT1 of the first thin film transistor TFT1 may include a low-temperature polysilicon semiconductor material, and the second active layer ACT2 of the second thin film transistor TFT2 may include an oxide semiconductor material. For example, the first active layer ACT1 of the first thin film transistor TFT1 may include an oxide semiconductor material, and the second active layer ACT2 of the second thin film transistor TFT2 may include a low-temperature polysilicon semiconductor material.

Transistors disposed in the display area DA may be used as follows.

For example, all transistors included in each subpixel SP may be implemented as the first thin film transistor TFT1. For example, all transistors included in each subpixel SP may be implemented as the second thin film transistor TFT2. For example, one or more transistors included in each subpixel SP may be implemented as the first thin film transistor TFT1, and the remaining one or more transistors may be implemented as the second thin film transistor TFT2. For example, each subpixel SP may include at least one first thin film transistor TFT1 and at least one second thin film transistor TFT2.

In an example where one or more transistors included in each subpixel SP are implemented as the first thin film transistor TFT1, and the remaining one or more transistors are implemented as the second thin film transistor TFT2, the following configurations may be applied.

For example, in each subpixel SP, a driving transistor DT may be implemented as the first thin film transistor TFT1, and the remaining one or more transistors (e.g., a scan transistor ST, an emission control transistor, and/or the like) except for the driving transistor DT may be implemented as the second thin film transistor TFT2.

For example, in each subpixel SP, a driving transistor DT may be implemented as the second thin film transistor TFT2, and the remaining one or more transistors (e.g., a scan transistor ST, an emission control transistor, and/or the like) except for the driving transistor DT may be implemented as the first thin film transistor TFT1.

In FIG. 4, the second thin film transistor TFT2 connected to a pixel electrode PE of a light emitting element ED may be a driving transistor DT or a transistor different from the driving transistor DT depending on the configuration of a corresponding subpixel circuit SPC. For example, in FIG. 4, the second thin film transistor TFT2 connected to the pixel electrode PE of the light emitting element ED may be an emission control transistor connected between a driving transistor DT and the light emitting element ED.

Transistors disposed in the non-display area NDA may be used as follows.

For example, the active layers of transistors included in the gate driving circuit of the gate-in-panel (GIP) type may include an oxide semiconductor material. For example, the active layers of transistors included in the gate driving circuit of the gate-in-panel (GIP) type may include a low-temperature polysilicon semiconductor material. For example, among the active layers of transistors included in the gate driving circuit of the gate-in-panel (GIP) type, some active layers may include a low-temperature polysilicon semiconductor material, and other active layers or the remaining one or more active layers may include an oxide semiconductor material.

The second active layer ACT2 of the second thin film transistor TFT2 may be located higher from the substrate 111 than the first active layer ACT1 of the first thin film transistor TFT1.

A first buffer layer 311 may be disposed under the first active layer ACT1 of the first thin film transistor TFT1, and a second buffer layer 321 may be disposed under the second active layer ACT2 of the second thin film transistor TFT2. For example, the first active layer ACT1 of the first thin film transistor TFT1 may be disposed on the first buffer layer 311, and the second active layer ACT2 of the second thin film transistor TFT2 may be disposed on the second buffer layer 321. The second buffer layer 321 may be disposed in a higher location than the first buffer layer 311 in the cross-sectional view.

The storage capacitor Cst may be disposed in several metal layers in the display panel 110. For example, the storage capacitor Cst may include a first capacitor electrode CAPE1 and a second capacitor electrode CAPE2.

The light emitting element part may include a plurality of light emitting elements ED disposed on at least one planarization layer 330. Each of the plurality of light emitting elements ED may include a pixel electrode PE, an intermediate layer EL, and a common electrode CE.

The encapsulation part may include an encapsulation layer 200 on the plurality of light emitting elements ED. The encapsulation layer 200 may be in the form of a single layer or multilayer, but embodiments of the present disclosure are not limited thereto. In addition to the encapsulation layer 200, the encapsulation part may further include at least one dam DAM to prevent or reduce a material included in the encapsulation layer 200 from overflowing. For example, when a second encapsulation layer 342 included in the encapsulation layer 200 is an organic encapsulation layer including an organic material, the dam DAM can prevent or reduce the organic encapsulation layer from overflowing.

Hereinafter, a vertical structure or stack-up structure of the display panel 110 is described in more detail with reference to FIG. 4.

Referring to FIG. 4, the first buffer layer 311 may be disposed on the substrate 111. The first buffer layer 311 may be in the form of a single layer or a multilayer, but aspects of the present disclosure are not limited thereto. In an example where the first buffer layer 311 includes a multilayer, the first buffer layer 311 may include a lower buffer layer 311a and an upper buffer layer 311b.

The first active layer ACT1 of the first thin film transistor TFT1 may be disposed on the first buffer layer 311. The first active layer ACT1 may include a channel region where a channel is formed, a source connection region on a first side of the channel region, and a drain connection region on a second opposing side of the channel region.

A first gate insulating layer 312 may be disposed on the first active layer ACT1 of the first thin film transistor TFT1. The first gate electrode E1a of the first thin film transistor TFT1 may be disposed on the first gate insulating layer 312. A first interlayer insulating layer 313 may be disposed on the first gate electrode E1a of the first thin film transistor TFT1. A metal layer in which the first gate electrode E1a of the first thin film transistor TFT1 is disposed may be referred to as a first gate metal layer.

The second buffer layer 321 may be disposed on the first interlayer insulating layer 313.

The second active layer ACT2 of the second thin film transistor TFT2 may be disposed on the second buffer layer 321. The second active layer ACT2 may include a channel region where a channel is formed, a source connection region on a first side of the channel region, and a drain connection region on a second opposing side of the channel region.

A second gate insulating layer 322 may be disposed on the second active layer ACT2 of the second thin film transistor TFT2. The second gate electrode E2a of the second thin film transistor TFT2 may be disposed on the second gate insulating layer 322. A second interlayer insulating layer 323 may be disposed on the second gate electrode E2a of the second thin film transistor TFT2. The second gate electrode E2a of the second thin film transistor TFT2 may be referred to as a second gate metal layer.

The first source electrode E1b and the first drain electrode E1c of the first thin film transistor TFT1 and the second source electrode E2b and the second drain electrode E2c of the second thin film transistor TFT2 may be disposed on the second interlayer insulating layer 323.

The first source electrode E1b and the first drain electrode E1c of the first thin film transistor TFT1 may be connected to the source connection region and the drain connection region of the first active layer ACT1, respectively, through openings of the second interlayer insulating layer 323, the second gate insulating layer 322, the second buffer layer 321, the first interlayer insulating layer 313, and the first gate insulating layer 312.

The second source electrode E2b and the second drain electrode E2c of the second thin film transistor TFT2 may be connected to the source connection region and the drain connection region of the second active layer ACT2, respectively, through openings of the second interlayer insulating layer 323 and the second gate insulating layer 322.

The first source electrode E1b and the first drain electrode E1c of the first thin film transistor TFT1, and the second source electrode E2b and the second drain electrode E2c of the second thin film transistor TFT2 may include a first source-drain metal and may be disposed in a first source-drain metal layer.

In one or more embodiments, the storage capacitor Cst may include the first capacitor electrode CAPE1 and the second capacitor electrode CAPE2. In one or more aspects, the storage capacitor Cst may include three or more capacitor electrodes, or may include two or more capacitors connected in parallel.

Each of the first capacitor electrode CAPE1 and the second capacitor electrode CAPE2 may be disposed in several metal layers disposed in the display panel 110.

In one or more aspects, the first capacitor electrode CAPE1 may include the same first gate metal as the first gate electrode E1a of the first thin film transistor TFT1 on the first gate insulating layer 312 and may be disposed in the first gate metal layer, but aspects of the present disclosure are not limited thereto. In one or more aspects, the second capacitor electrode CAPE2 may be disposed on the first interlayer insulating layer 313.

The second source electrode E2b of the second thin film transistor TFT2 may be electrically connected to the second capacitor electrode CAPE2 through openings of the second interlayer insulating layer 323, the second gate insulating layer 322, and the second buffer layer 321.

For example, when the stack-up configuration of FIG. 4 is applied to the subpixel circuit of FIG. 2, the first thin film transistor TFT1 may be the scan transistor ST of FIG. 2, and the second thin film transistor TFT2 may be the driving transistor DT of FIG. 2.

In one or more embodiments, the transistor part may further include a first shield pattern BSM1 disposed on the substrate 111. The first shield pattern BSM1 may be overlapped with the first active layer ACT1 of the first thin film transistor TFT1. The first shield pattern BSM1 may be disposed under the first active layer ACT1 of the first thin film transistor TFT1. For example, the first shield pattern BSM1 may be disposed between the substrate 111 and the first buffer layer 311 or may be disposed between the lower buffer layer 311a and the upper buffer layer 311b.

The transistor part may further include a second shield pattern BSM2 disposed on the substrate 111. The second shield pattern BSM2 may be overlapped with the second active layer ACT2 of the second thin film transistor TFT2. The second shield pattern BSM2 may be disposed under the second active layer ACT2 of the second thin film transistor TFT2. For example, the second shield pattern BSM2 may be disposed in a metal layer between the first interlayer insulating layer 313 and the second buffer layer 321. The second shield pattern BSM2 may be disposed in the same metal layer as the second capacitor electrode CAPE2, but aspects of the present disclosure are not limited thereto. For example, the second shield pattern BSM2 may be disposed in the same first gate metal layer as the first gate electrode E1a of the first thin film transistor TFT1.

The planarization layer 330 may be disposed on the first thin film transistor TFT1 and the second thin film transistor TFT2, and may be disposed under the light emitting element ED. The planarization layer 330 may be an organic insulating layer including an organic insulating material.

For example, the planarization layer 330 may be in the form of a single layer. For example, the planarization layer 330 may include two layers. The planarization layer 330 may include a first planarization layer 331 and a second planarization layer 332. For example, the planarization layer 330 may include three or more layers. However, aspects of the present disclosure are not limited thereto.

The first planarization layer 331 may be disposed on the first source electrode E1b and the first drain electrode E1c of the first thin film transistor TFT1 and the second source electrode E2b and the second drain electrode E2c of the second thin film transistor TFT2. For example, the first planarization layer 331 may be disposed on the first thin film transistor TFT1 and the second thin film transistor TFT2. For example, the first planarization layer 331 may be disposed such that it covers both the first thin film transistor TFT1 and the second thin film transistor TFT2.

A connection electrode RE may be disposed on the first planarization layer 3531. The connection electrode RE may electrically connect the second source electrode E2b of the second thin film transistor TFT2 and the pixel electrode PE.

The connection electrode RE may be electrically connected to the second source electrode E2b of the second thin film transistor TFT2 through a opening of the first planarization layer 331. The second source electrode E2b of the second thin film transistor TFT2 may be electrically connected to the second capacitor electrode CAPE2 of the storage capacitor Cst.

The connection electrode RE may be disposed in a second source-drain metal layer on the first planarization layer 331 and include a second source-drain metal.

The second planarization layer 332 may be disposed on the connection electrode RE.

The light emitting element part may be disposed on the second planarization layer 332. The light emitting element ED may be formed on the second planarization layer 332. The light emitting element ED may include the pixel electrode PE, the intermediate layer EL, and the common electrode CE. A light emitting area of the light emitting element ED may be formed by an area where the pixel electrode PE, the intermediate layer EL, and the common electrode CE overlap with and contact each other.

The pixel electrode PE may be disposed on the second planarization layer 332. The pixel electrode PE may be electrically connected to the connection electrode RE through a opening of the second planarization layer 332.

The bank 340 may be disposed on the pixel electrode PE. An opening of the bank 340 may expose a portion of the pixel electrode PE to form a light emitting area. The opening of the bank 340 may overlap with a portion of the pixel electrode PE.

For example, the bank 340 may include a material including a black pigment, or an organic material including a benzocyclobutene resin, a polyimide resin, an acrylic resin, a photosensitive polymer, or the like. However, aspects of the present disclosure are not limited thereto. In an example where the bank 340 includes a material including a black pigment or a black dye, the bank 340 may be a black bank. In the example where the bank 340 includes a material including a black pigment or a black dye, the luminance of the display device can be further improved because light from the outside or light reflected from the outside can be blocked.

The intermediate layer EL of the light emitting element ED may be disposed on a portion of the pixel electrode PE and the bank 340. The common electrode CE may be disposed on the intermediate layer EL.

The encapsulation part may be disposed on the light emitting element part and be located on the common electrode CE. The encapsulation part may include an encapsulation layer 200 disposed on the common electrode CE.

The encapsulation layer 200 can prevent or reduce moisture or oxygen from penetrating into the light emitting element ED. For example, the encapsulation layer 200 can prevent or reduce moisture or oxygen from penetrating into an organic material included in the intermediate layer EL of the light emitting element ED. In one or more aspects, the encapsulation layer 200 may be in the form a single layer or multilayer, but aspects of the present disclosure are not limited thereto.

For example, the encapsulation layer 200 may include a first encapsulation layer 341, a second encapsulation layer 342, and a third encapsulation layer 343. For example, the first encapsulation layer 341 and the third encapsulation layer 343 may include an inorganic material, and the second encapsulation layer 342 may include an organic material. However, aspects of the present disclosure are not limited thereto.

In one or more embodiments, a touch sensor may be embedded in the display panel 110. In this implementation, the display panel 110 may include a touch sensor layer 210 disposed on the encapsulation layer 200 and including the touch sensor.

The touch sensor layer 210 may include a plurality of touch electrodes TE serving as the touch sensor and include at least one touch metal layer for forming the plurality of touch electrodes TE.

For example, to form the plurality of touch electrodes TE, the touch sensor layer 210 may include a first touch metal layer in which a plurality of first touch metals TM1 are disposed, and a second touch metal layer in which a plurality of second touch metals TM2 are disposed. In this implementation, the touch sensor layer 210 may further include a touch interlayer insulating layer 352 disposed between the first touch metal layer and the second touch metal layer.

For example, one of the first touch metal layer and the second touch metal layer may be a sensor metal layer, and the other may be a bridge metal layer.

For example, the first touch metal layer may be a bridge metal layer, and the second touch metal layer may be a sensor metal layer. In this implementation, the plurality of second touch metals TM2 disposed in the second touch metal layer may be sensor metals forming the touch sensor, and the plurality of first touch metals TM1 disposed in the first touch metal layer may be bridge metals electrically connecting the plurality of second touch metals TM2, which are the sensor metals. In one or more embodiments, two or more second touch metals TM2 and at least one first touch metal TM1 may form one first touch electrode TE1. In this implementation, the two or more second touch electrodes TE2 may be electrically connected by at least one first touch metal TM1.

In one or more embodiments, the first touch metal layer may be a sensor metal layer, and the second touch metal layer may be a bridge metal layer. In this implementation, the plurality of first touch metals TM1 disposed in the first touch metal layer may be sensor metals forming the touch sensor, and the plurality of second touch metals TM2 disposed in the second touch metal layer may be bridge metals electrically connecting the plurality of first touch metals TM1, which are the sensor metals.

In one or more embodiments, each of the first touch metal layer and the second touch metal layer may be a sensor metal layer and a bridge metal layer. For example, the first touch metal layer may be a sensor metal layer and a bridge metal layer, and the second touch metal layer may be a sensor metal layer and a bridge metal layer. In this implementation, the plurality of first touch metals TM1 disposed in the first touch metal layer may include sensor metals and bridge metals, and the plurality of second touch metals TM2 disposed in the second touch metal layer may include sensor metals and bridge metals.

The touch sensor layer 210 may further include a touch buffer layer 351 disposed on the encapsulation layer 200. The touch buffer layer 351 may be disposed between the encapsulation layer 200 and the touch metal layer. For example, the first touch metal layer may be disposed on the touch buffer layer 351, and the touch interlayer insulating layer 352 may be disposed on the first touch metal layer.

The touch sensor layer 210 may further include a touch protection layer 353 disposed such that the touch protection layer 353 covers the touch metal layers. For example, the touch protection layer 353 may be disposed on the second touch metal layer.

For example, the touch buffer layer 351 may be an inorganic layer including an inorganic insulating material or an organic layer including an organic insulating material. The touch interlayer insulating layer 352 may be an inorganic layer including an inorganic insulating material or an organic layer including an organic insulating material. The touch protection layer 353 may be an inorganic layer including an inorganic insulating material or an organic layer including an organic insulating material.

For example, at least one of the touch buffer layer 351 and the touch interlayer insulating layer 352 may be disposed to extend from the display area DA to the non-display area NDA. The touch protection layer 353 may be disposed to extend from the display area DA to the non-display area NDA.

A touch routing line TL may electrically interconnect a touch electrode TE and a touch pad TP. The touch routing line TL may be formed by at least one of the first touch metal TM1 and the second touch metal TM2.

For example, the touch routing line TL may be formed by the first touch metal TM1. For example, the touch routing line TL may be formed by the second touch metal TM2. For example, the touch routing line TL may be formed by the first touch metal TM1 and the second touch metal TM2. In an example where one touch routing line TL is formed by the first touch metal TM1 and the second touch metal TM2, the first touch metal TM1 and the second touch metal TM2 included in the touch routing line TL may be electrically connected through a opening in the insulating layer 352.

For example, one touch routing line TL may include a plurality of line portions, and each of the plurality of line portions may be a single line portion or a double line portion. For example, the single line portion may be a line portion with one signal path, and the double line portion may be a line portion with two signal paths connected in parallel.

The touch routing line TL may extend along an inclined surface of the encapsulation layer 200, extend over an upper portion of at least one dam (DAM1 and/or DAM2), and reach a touch pad TP.

The touch buffer layer 351 may have an opening to expose at least a portion of the touch pad TP. The touch routing line TL may be electrically connected to the touch pad TP through the opening of the touch buffer layer 351. The touch interlayer insulating layer 352 may be disposed on a portion of the touch routing line TL and extend to an area where the touch pad TP is disposed. The touch protection layer 353 may be disposed in the display area DA but not the non-display area or may extend to the non-display area NDA and be disposed on the touch routing line TL. In one or more embodiments, the touch protection layer 353 may extend further to an upper portion of the touch pad TP.

Each of a plurality of touch electrodes TE may be a mesh-type electrode configured to have a mesh and having a plurality of openings. In this implementation, each of the plurality of touch electrodes TE may include at least one second touch metal TM2. However, aspects of the present disclosure are not limited thereto.

For example, the plurality of touch electrodes TE may include at least one first touch electrode TE1 and at least one second touch electrode TE2. In an example where the first touch metal layer is a bridge metal layer and the second touch metal layer is a sensor metal layer, two or more second touch metals TM2 included in a first touch electrode TE1, which is the touch sensor, may be electrically connected through at least one first touch metal TM1, which is the bridge metal. For example, two second touch metals TM2 spaced apart from each other may be electrically connected by a first touch metal TM1 to form one first touch electrode TE1.

The plurality of first touch metals TM1 and the plurality of second touch metals TM2 may be disposed not to overlap (e.g., non-overlapping) with the light emitting element ED. The plurality of first touch metals TM1 and the plurality of second touch metals TM2 may overlap with the bank 340. According to these configurations, the display panel 110 can provide an advantage of improving the emission efficiency of the light emitting element ED.

The touch routing line TL may connect the touch pad TP disposed in a pad area PA of a second non-display area NDA2 and the first touch electrode TE1 disposed in the display area DA. In this implementation, the touch routing line TL may be disposed across the second non-display area NDA2, a bending area BA, and a first non-display area NDA1.

The touch routing line TL may include a first line portion TLa, a second line portion TLb, and a third line portion TLc. For example, the touch routing line TL may include the first line portion TLa and the second line portion TLb disposed in the first non-display area NDA1 and the second non-display area NDA2, and the third line portion TLc disposed in the bending area BA. The third line portion TLc may connect two first line portions TLa or the first line portion TLa and the second line portion TLb.

The first line portion TLa of the touch routing line TL may be a single line portion and further include a third touch metal layer in which a third touch metal TM3 is disposed.

The first line portion TLa of the touch routing line TL may be disposed to extend along an inclined surface of the encapsulation layer 200 and further extend over at least one dam (DAM1 and/or dam2).

For example, the first line portion TLa of the touch routing line TL may be connected to the third line portion TLc of the touch routing line TL through at least one of the first touch metal layer and the second touch metal layer.

The second line portion TLb of the touch routing line TL may include at least one of the first touch metal layer in which the first touch metal TM1 is disposed and the second touch metal layer in which the second touch metal TM2 is disposed.

For example, the second line portion TLb of the touch routing line TL may be formed by the second touch metal layer. For another example, the second line portion TLb of the touch routing line TL may be formed by an electrical connection of the first touch metal layer and the second touch metal layer.

For example, the second line portion TLb of the touch routing line TL may be electrically connected to the touch pad TP through a contact hole (opening) through the second planarization layer 332, the touch buffer layer 351, and the touch interlayer insulation layer 352.

For example, the third line portion TLc of the touch routing line TL may be connected to the second line portion TLb of the touch routing line TL.

The third line portion TLc of the touch routing line TL may include a metal layer different from the first to third touch metal layers in which the first, second and third touch metals (TM1, TM2, and TM3) are disposed. For example, the metal layer included in the third line portion TLc of the touch routing line TL may be the same as a metal layer in which one or more electrodes or lines for display driving are disposed. For example, the metal layer included in the third line portion TLc of the touch routing line TL may include a metal layer in which the pixel electrode PE is disposed, but embodiments of the present disclosure are not limited thereto.

The touch pad TP may be electrically connected to the second line portion TLb of the touch routing line TL and may include a metal layer different from the first to third touch metal layers. For example, the metal layer included in the touch pad TP may be the same as a metal layer in which one or more electrodes or lines for display driving are disposed. For example, the metal layer included in the touch pad TP may include a metal layer in which the pixel electrode PE is disposed, but embodiments of the present disclosure are not limited thereto.

In one or more embodiments, the display panel 110 may further include a common voltage line VSSL to which a common voltage VSS is applied, and a connection pattern CP for connecting the common electrode CE and the common voltage line VSSL. For example, the connection pattern CP may include the same material as the pixel electrode PE. The connection pattern may include a first connection pattern CP1 and a second connection pattern CP2. For example, the first connection pattern CP1 may connect the common electrode CE and the second connection pattern CP2, and the second connection pattern CP2 may connect the first connection pattern CP1 and the first common voltage line VSSL, but aspects of the present disclosure are not limited thereto.

As described above, the common electrode CE disposed in the display area DA of the display panel 110 and the common voltage line VSSL disposed in the non-display area NDA surrounding an outer edge of the display area DA may be electrically connected to each other. However, since the common voltage line VSSL is disposed in the non-display area NDA, this configuration may cause the luminance uniformity to decrease and the bezel size to increase, and therefore, make it difficult to have a narrow bezel.

Hereinafter, in one or more embodiments, discussions are provided for example embodiments of the display device 100 capable of improving luminance uniformity of the display panel 100 by including a structure in which a common voltage line VSSL and a common electrode CE contact each other in a display area DA of the display panel 110, significantly reducing the bezel size of the display device 100 by including a structure where the common voltage line VSSL is integrated in the display area DA, and providing an aesthetically satisfying design through a narrow bezel design.

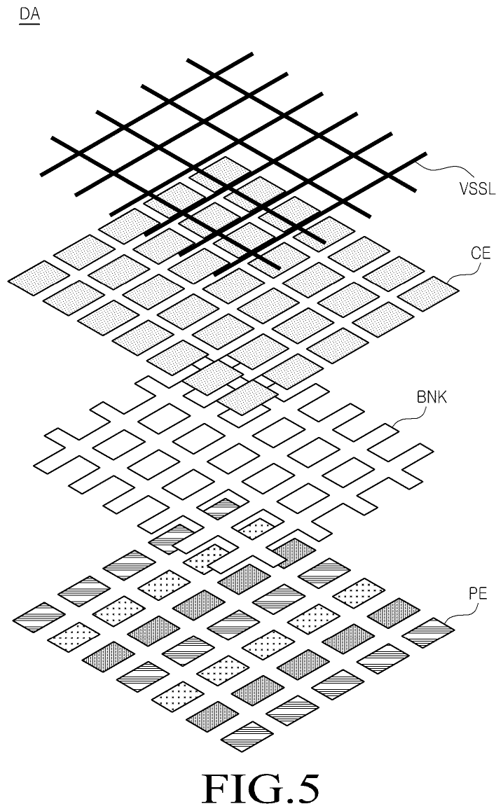

FIG. 5 illustrates an example structure of the display area DA according to aspects of the present disclosure.

Referring to FIG. 5, in one or more example embodiments, the display area DA may include at least one pixel electrode PE, a bank BNK, at least one common electrode CE, and at least one common voltage line VSSL, but embodiments of the present disclosure are not limited thereto.

For example, a plurality of pixel electrodes PE may be disposed in the display area DA. For example, the plurality of pixel electrodes PE may be anodes, but aspects of the present disclosure are not limited thereto.

The common electrode CE may be disposed in the display area DA. For example, the common electrode CE may be disposed over the plurality of pixel electrodes PE, but embodiments of the present disclosure are not limited thereto. For example, the common electrode CE may be a cathode, but aspects of the present disclosure are not limited thereto.

The bank BNK may be disposed in the display area DA. For example, the bank BNK may overlap with areas between the plurality of pixel electrodes PE and be disposed in a matrix form, but aspects of the present disclosure are not limited thereto. For example, the bank BNK may be disposed between the plurality of pixel electrodes PE and the common electrode CE, but aspects of the present disclosure are not limited thereto.

The common voltage line VSSL may be disposed in the display area DA. For example, the common voltage line VSSL may be disposed in a matrix form on the bank BNK, but embodiments of the present disclosure are not limited thereto. For example, at least a portion of the common electrode CE may extend onto the bank BNK and be electrically connected to the common voltage line VSSL, but aspects of the present disclosure are not limited thereto.

For example, a width of the bank BNK may be greater than a width of the common voltage line VSSL, but aspects of the present disclosure are not limited thereto.

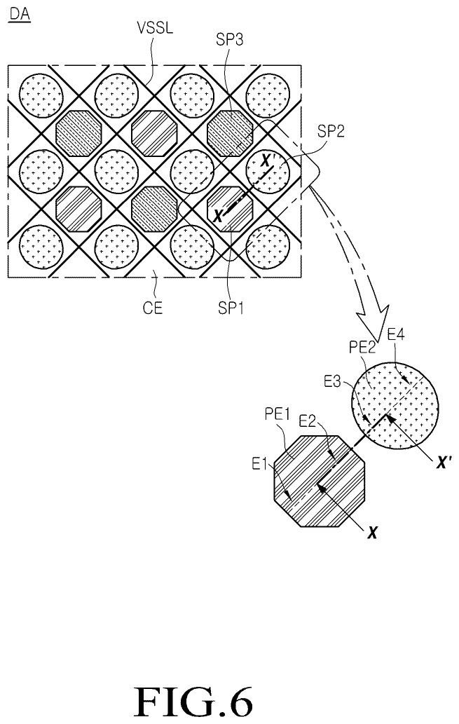

FIG. 6 is an example plan view of the display area DA according to embodiments of the present disclosure.

Referring to FIG. 6, in one or more example embodiments, the display area DA may include a plurality of light emitting areas (EA1, EA2, EA3), at least one common electrode CE, and at least one common voltage line VSSL, but aspects of the present disclosure are not limited thereto.

The plurality of light emitting areas (EA1, EA2, EA3) may be disposed in the display area DA. For example, the plurality of light emitting areas (EA1, EA2, EA3) may overlap with a plurality of subpixels (SP1, SP2, SP3) including a plurality of light emitting elements, but aspects of the present disclosure are not limited thereto.

For example, the plurality of light emitting elements may include a first light emitting element located in a first light emitting area EA1 among the plurality of light emitting areas and a second light emitting element located in a second light emitting area EA2 among the plurality of light emitting areas, but aspects of the present disclosure are not limited thereto.

For example, a first pixel electrode PE1 of the first light emitting element and a second pixel electrode PE2 of the second light emitting element may be disposed adjacent to each other, but aspects of the present disclosure are not limited thereto. For example, the first pixel electrode PE1 and the second pixel electrode PE2 may be spaced apart, but embodiments of the present disclosure are not limited thereto.

For example, the first pixel electrode PE1 of the first light emitting element may include a first edge E1 and an opposing second edge E2, but embodiments of the present disclosure are not limited thereto. For example, the second pixel electrode PE2 of the second light emitting element may include a third edge E3 and a fourth opposing edge E4, but embodiments of the present disclosure are not limited thereto. For example, the second edge E2 may be disposed adjacent to the third edge E3, but embodiments of the present disclosure are not limited thereto.

For example, the common electrode CE may be disposed to overlap with a plurality of light emitting areas, but embodiments of the present disclosure are not limited thereto. For example, the common electrode CE may be a cathode, but embodiments of the present disclosure are not limited thereto.

For example, the common voltage line VSSL may deliver a common voltage. For example, the common voltage line VSSL may be disposed in a mesh form in the display area, but aspects of the present disclosure are not limited thereto. For example, the common voltage line VSSL may be electrically connected to the common electrode CE in the display area, but aspects of the present disclosure are not limited thereto.

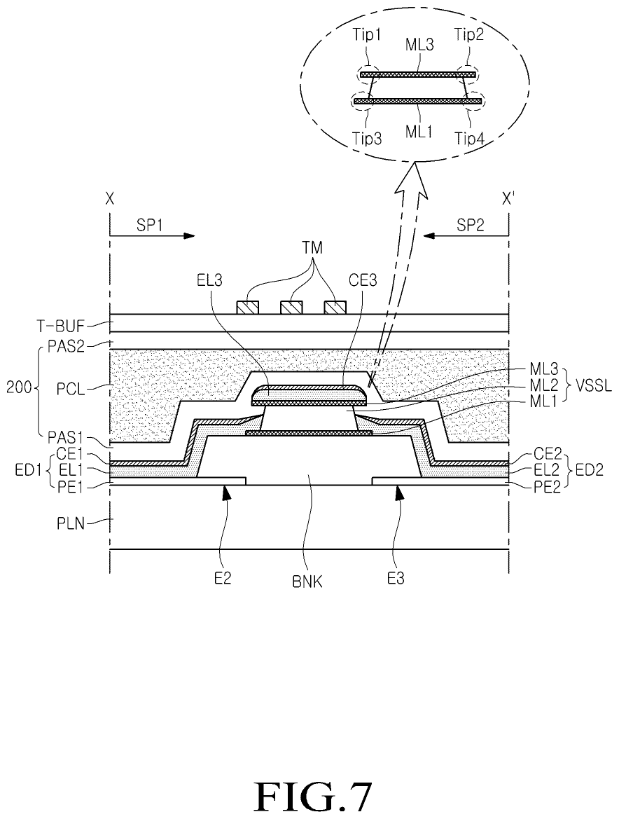

FIGS. 7 to 11 are example cross-sectional views taken along line X-X′ of FIG. 6 according to embodiments of the present disclosure. Hereinafter, discussions for features equal, substantially equal, or similar to the features described with reference to FIGS. 5 and 6 are omitted for simplicity.

Referring to FIG. 7, in one or more example embodiments, the display panel 110 may include a substrate including a display area where an image is displayed, a planarization layer PLN, a plurality of light emitting elements, a bank BNK, a common voltage line VSSL, an organic layer EL3, a metal pattern CE3, an encapsulation layer 200, and a plurality of touch metals TM.

The planarization layer PLN may be disposed on the substrate. For example, the planarization layer PLN may be an organic insulating layer including an organic insulating material, but aspects of the present disclosure are not limited thereto.

For example, the planarization layer PLN may be in the form of a single layer. In another example, the planarization layer PLN may include two layers. In another example, the planarization layer PLN may include three or more layers. However, aspects of the present disclosure are not limited thereto.

The plurality of light emitting elements may include a first light emitting element ED1 located in an area of a first subpixel SP1 among the plurality of subpixels and a second light emitting element ED2 located in an area of a second subpixel SP2 among the plurality of subpixels.

For example, the first light emitting element ED1 may be located in the area of the first subpixel SP1 among the plurality of subpixels. The first light emitting element ED1 may include, but is not limited to, a first pixel electrode PE1, a first intermediate layer EL1, and a first common electrode CE1.

For example, the second light emitting element ED2 may be located in the area of the second subpixel SP2 among the plurality of subpixels. The second light emitting element ED2 may include, but is not limited to, a second pixel electrode PE2, a second intermediate layer EL2, and a second common electrode CE2.

For example, the first pixel electrode PE1 may be located in the area of the first subpixel SP1 and be disposed on the planarization layer PLN, but embodiments of the present disclosure are not limited thereto.

For example, the second pixel electrode PE2 may be located in the area of the second subpixel SP2, disposed on the planarization layer PLN, and spaced apart from the first pixel electrode PE1, but aspects of the present disclosure are not limited thereto.

The bank BNK may be disposed on the second edge E2 of the first pixel electrode PE1 and the third edge E3 of the second pixel electrode PE2. In one or more aspects, the bank BNK may be disposed in a matrix form, but aspects of the present disclosure are not limited thereto.

For example, the bank BNK may be formed with a flat upper surface, but aspects of the present disclosure are not limited thereto.

For example, the bank BNK may include a material including a black pigment or an organic material such as a benzocyclobutene resin, a polyimide resin, an acrylic resin, a photosensitive polymer, or the like, but embodiments of the present disclosure are not limited thereto. When the bank BNK includes a material including a black pigment or a black dye, this bank BNK may be a black bank. In the example where the bank BNK includes a material including a black pigment or a black dye, the luminance of the display device 100 can be further improved because light from the outside or light reflected from the outside can be blocked.

For example, the first intermediate layer EL1 may be disposed on the first pixel electrode PE1 and extend along at least one side surface of the bank BNK, but aspects of the present disclosure are not limited thereto.

For example, the second intermediate layer EL2 may be disposed on the second pixel electrode PE2 and extend along at least one side surface of the bank BNK, but aspects of the present disclosure are not limited thereto.

For example, the organic layer EL3 may be disposed on the bank BNK, but embodiments of the present disclosure are not limited thereto. For example, the organic layer EL3 may be spaced apart from the first intermediate layer EL1 and the second intermediate layer EL2, but embodiments of the present disclosure are not limited thereto. For example, the organic layer EL3 may include an organic material included in the first intermediate layer EL1 and the second intermediate layer EL2, but embodiments of the present disclosure are not limited thereto.

The common voltage line VSSL may deliver a common voltage. For example, the common voltage line VSSL may be disposed on the bank BNK, but embodiments of the present disclosure are not limited thereto. For example, the common voltage line VSSL may be disposed in a mesh form in the display area, but aspects of the present disclosure are not limited thereto.

For example, the common voltage line VSSL may include, but is not limited to, a lower metal line ML1, an intermediate metal line ML2 on the lower metal line ML1, and an upper metal line ML3 on the intermediate metal line ML2.

For example, a size of a lower surface of the common voltage line VSSL may be less than that of an upper surface of the bank BNK, but embodiments of the present disclosure are not limited thereto. For example, a width of the common voltage line VSSL may be less than that of the bank BNK, but embodiments of the present disclosure are not limited thereto.

For example, the upper metal line ML3 may include a first protrusion Tip1 protruding beyond a side edge (e.g., an upper left-side edge) of the intermediate metal line ML2, and a second protrusion Tip2 protruding beyond another side edge (e.g., an upper right-side edge) of the intermediate metal line ML2, but embodiments of the present disclosure are not limited thereto.

For example, the lower metal line ML1 may include a third protrusion Tip3 protruding beyond a side edge (e.g., a lower left-side edge) of the intermediate metal line ML2, and a fourth protrusion Tip4 protruding beyond another side edge (e.g., a lower right-side edge) of the intermediate metal line ML2, but embodiments of the present disclosure are not limited thereto.

For example, the first common electrode CE1 may be disposed on the first intermediate layer EL1 and be electrically connected to one side of the common voltage line VSSL, but aspects of the present disclosure are not limited thereto. For example, the first common electrode CE1 may contact at least one of the first protrusion Tip1 and a side surface of the intermediate metal line ML2, but aspects of the present disclosure are not limited thereto.

For example, the second common electrode CE2 may be disposed on the second intermediate layer EL2 and be electrically connected to the other side of the common voltage line VSSL, but aspects of the present disclosure are not limited thereto. For example, the second common electrode CE2 may contact at least one of the second protrusion Tip2 and a side surface of the intermediate metal line ML2, but aspects of the present disclosure are not limited thereto.

For example, the metal pattern CE3 may be disposed on the organic layer EL3, but aspects of the present disclosure are not limited thereto. For example, the metal pattern CE3 may be spaced apart from the first common electrode CE1 and the second common electrode CE2, but aspects of the present disclosure are not limited thereto. For example, the metal pattern CE3 may include the same metal as the first common electrode CE1 and the second common electrode CE2 and be in an electrically floating state. However, aspects of the present disclosure are not limited thereto.

For example, at least one of the organic layer EL3 and the metal pattern CE3 may be disposed in a mesh form in the display area, but aspects of the present disclosure are not limited thereto.

The encapsulation layer 200 can prevent or reduce external moisture or oxygen from penetrating into circuit elements (e.g., light emitting areas), but aspects of the present disclosure are not limited thereto. The encapsulation layer 200 may be configured in various forms to prevent or reduce light emitting elements from contacting moisture or oxygen.

The encapsulation layer 200 may be in the form of a single layer or a multilayer, but aspects of the present disclosure are not limited thereto. For example, the encapsulation layer 200 may include two or more layers in which at least one organic layer and at least one inorganic layer are alternately stacked, but aspects of the present disclosure are not limited thereto. For example, the encapsulation layer 200 may include a first inorganic layer PAS1, a first organic layer PCL, and a second inorganic layer PAS2, but aspects of the present disclosure are not limited thereto.

For example, the first inorganic layer PAS1 and the second inorganic layer PAS2 may be inorganic encapsulation layers, and the first organic layer PCL may be an organic encapsulation layer, but aspects of the present disclosure are not limited thereto.

In one or more embodiments, the display panel 110 may include a touch sensor. In this configuration, the display panel 110 may include a touch sensor layer disposed on the encapsulation layer 200 and allowing the touch sensor to be disposed.

For example, the touch sensor layer may include a plurality of touch metals TM. For example, a touch buffer layer T-BUF may be disposed in the touch sensor layer, but aspects of the present disclosure are not limited thereto. The plurality of touch metals TM may be disposed on the touch buffer layer T-BUF, but aspects of the present disclosure are not limited thereto.

For example, the touch buffer layer T-BUF may be an inorganic layer including an inorganic insulating material or an organic layer including an organic insulating material, but aspects of the present disclosure are not limited thereto.

For example, one or more touch electrodes may be configured with the plurality of touch metals TM, but aspects of the present disclosure are not limited thereto. For example, the plurality of touch metals TM may include sensor metals and bridge metals, but aspects of the present disclosure are not limited thereto. For example, the plurality of touch metals TM may form touch routing lines, but aspects of the present disclosure are not limited thereto.

For example, at least one of the plurality of touch metals TM may overlap with at least a portion of the common voltage line VSSL, but aspects of the present disclosure are not limited thereto. For example, the plurality of touch metals TM may be disposed not to overlap with a plurality of light emitting elements, but aspects of the present disclosure are not limited thereto. For example, the plurality of touch metals TM may overlap with the bank BNK, but aspects of the present disclosure are not limited thereto.

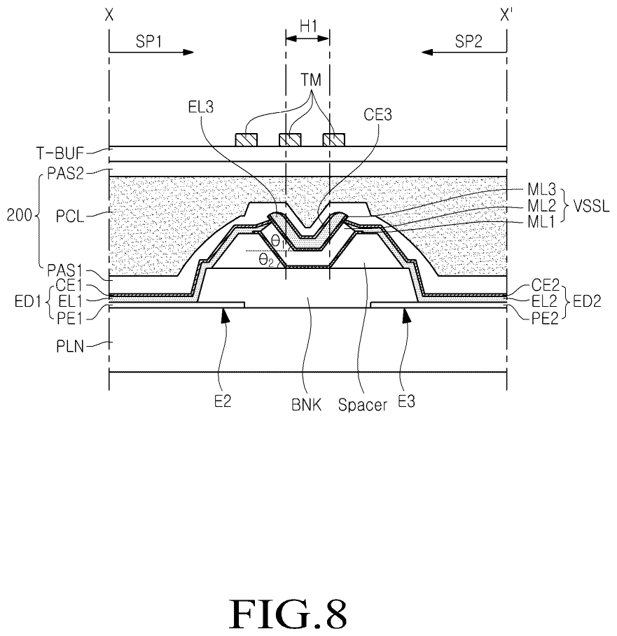

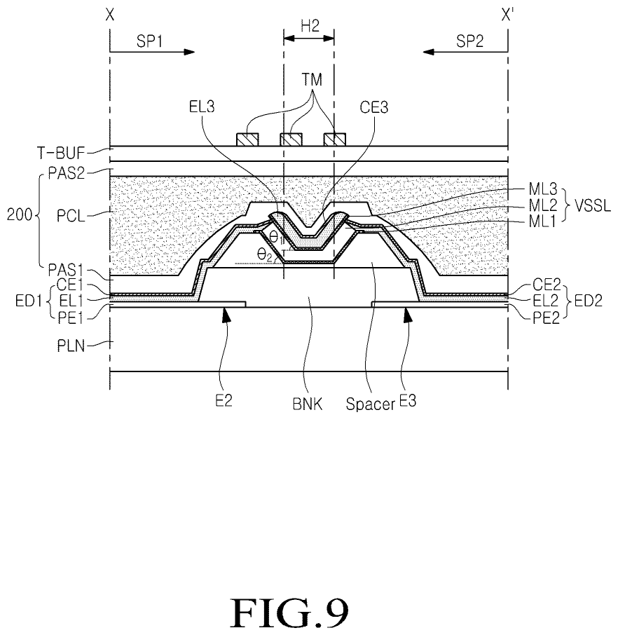

Referring to FIGS. 8 and 9, in one or more example embodiments, the display panel 110 may further include at least one spacer Spacer disposed on the bank BNK.

For example, the spacer Spacer may have a opening H1 or a groove H2. For example, at least one side surface of the opening H1 or the groove H2 may be inclined at a certain angle to an upper or lower surface of the bank BNK, but aspects of the present disclosure are not limited thereto.

For example, a common voltage line VSSL may be disposed in the opening H1 or the groove H2 of the spacer Spacer, and extend along at least one side surface of the opening H1 or the groove H2 of the spacer Spacer. However, embodiments of the present disclosure are not limited thereto. For example, at least a portion of the common voltage line VSSL may protrude beyond an upper surface of the spacer Spacer and be electrically connected to the first common electrode CE1 and the second common electrode CE2, but embodiments of the present disclosure are not limited thereto.

For example, a first angle θ1 of a portion of the common voltage line VSSL disposed on at least one side surface of the opening H1 or the groove H2 of the spacer Spacer to the upper surface of the bank BNK may correspond to a second angle θ2 of the at least one side surface of the opening H1 or the groove H2 of the spacer Spacer to the upper surface of the bank BNK, but aspects of the present disclosure are not limited thereto.

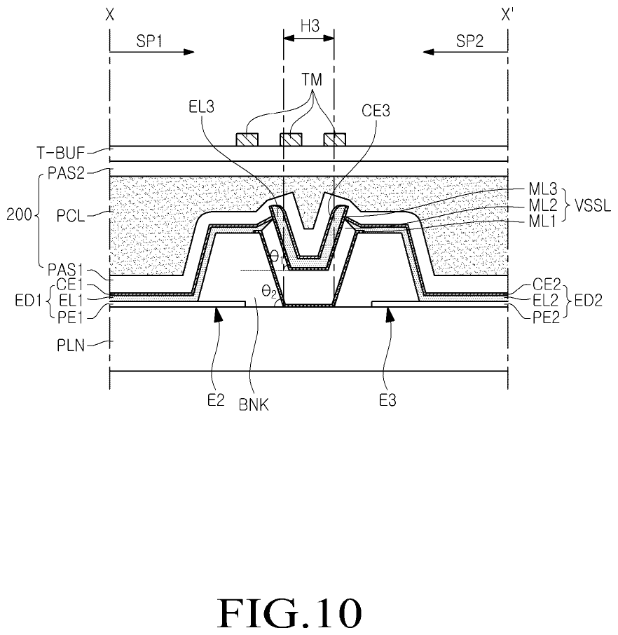

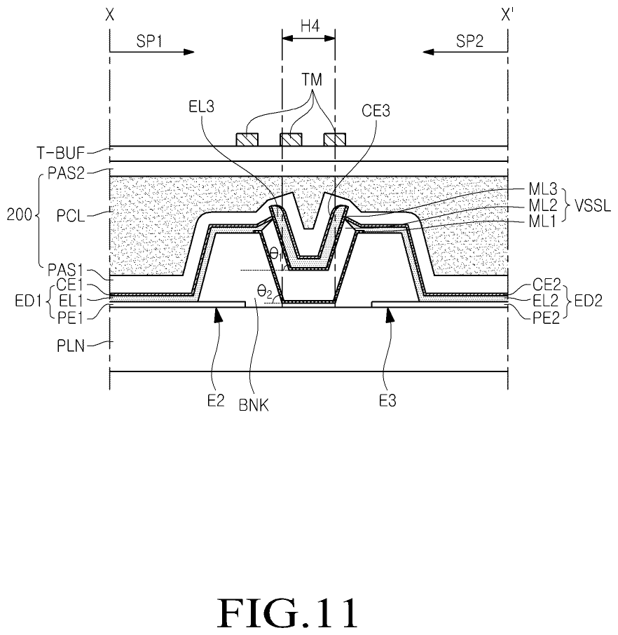

Referring to FIGS. 10 and 11, in one or more example embodiments, the bank BNK of the display panel 110 may include, or further include, a opening H3 or a groove H4. For example, at least one side surface of the opening H3 or the groove H4 of the bank BNK may be inclined at a certain angle to an upper or lower surface of the bank BNK or the planarization layer PLN, but aspects of the present disclosure are not limited thereto.

For example, a common voltage line VSSL may be disposed in the opening H3 or the groove H4 of the bank BNK, and extend along at least one side surface of the opening H3 or the groove H4 of the bank BNK, but embodiments of the present disclosure are not limited thereto. For example, at least a portion of the common voltage line VSSL may protrude beyond the upper surface of the bank BNK and be electrically connected to the first common electrode CE1 and the second common electrode CE2, but aspects of the present disclosure are not limited thereto.

For example, a first angle θ1 of a portion of the common voltage line VSSL disposed in at least one side surface of the opening H3 or the groove H4 of the bank BNK to an upper surface of the planarization layer PLN may correspond to a second angle θ2 of the at least one side surface of the opening H3 or the groove H4 of the bank BNK with the upper surface of the planarization layer PLN, but embodiments of the present disclosure are not limited thereto.

As discussed above, referring to FIGS. 5 to 11, as the common voltage line VSSL and the common electrode CE contact each other in the display area DA of the display panel 110, the luminance uniformity of the display panel 100 can be improved, and as the common voltage line VSSL is integrated in the display area DA, the bezel size of the display device 100 can be significantly reduced. Further, an aesthetically satisfying design can be provided through the narrow bezel design.

The examples, embodiments, and embodiments for the display device 100 and the display panel 110 described herein may be described as follows.

According to the one or more example embodiments described herein, a display device can be provided that includes a substrate including a display area where an image is displayed, a planarization layer disposed on the substrate, a first pixel electrode located in an area of a first subpixel among a plurality of subpixels, disposed on the planarization layer, and including a first edge and a second edge, a second pixel electrode located in an area of a second subpixel among the plurality of subpixels, disposed on the planarization layer, spaced from the first pixel electrode, and including a third edge adjacent to the second edge and a fourth edge, a bank disposed on the second edge of the first pixel electrode and the third edge of the second pixel electrode, a common voltage line disposed on the bank and delivering a common voltage, a first intermediate layer disposed on the first pixel electrode and extending along a first side surface of the bank, a second intermediate layer disposed on the second pixel electrode and extending along a second side surface of the bank, an organic layer disposed on the bank and spaced from the first intermediate layer and the second intermediate layer, a first common electrode disposed on the first intermediate layer and electrically connected to one side of the common voltage line, a second common electrode disposed on the second intermediate layer and electrically connected to the other side of the common voltage line, and a metal pattern disposed on the organic layer and spaced apart from the first common electrode and the second common electrode.

In one or more embodiments, the organic layer may include an organic material included in the first intermediate layer and the second intermediate layer.

In one or more embodiments, the metal pattern may include the same metal as the first common electrode and the second common electrode and be in an electrically floating state.

In one or more embodiments, the common voltage line may include a lower metal line, an intermediate metal line on the lower metal line, and an upper metal line on the intermediate metal line.

In one or more embodiments, the upper metal line may include a first protrusion protruding beyond an edge of one side of the intermediate metal line, and a second protrusion protruding beyond an edge of the other side of the intermediate metal line.

In one or more embodiments, the first common electrode may contact at least one of the first protrusion and a side portion of the intermediate metal line, and the second common electrode may contact at least one of the second protrusion and a side portion of the intermediate metal line.

In one or more embodiments, the common voltage line may be disposed in a mesh form in the display area.

In one or more embodiments, at least one of the organic layer and the metal pattern may be disposed in a mesh form in the display area.

In one or more embodiments, a size of a lower surface of the common voltage line may be less than that of an upper surface of the bank, and the upper surface of the bank may be flat.

In one or more embodiments, the display device may further include a spacer disposed on the bank and including a opening or a groove, and at least one side surface of the opening or the groove may be inclined.

In one or more embodiments, the common voltage line may be disposed in the opening or the groove and extend along the at least one side surface of the opening or the groove, and at least a portion of the common voltage line may protrude beyond an upper surface of the spacer and be electrically connected to the first common electrode and the second common electrode.

In one or more embodiments, a first angle of a portion of the common voltage line disposed on the at least one side surface of the opening or the groove to an upper surface of the bank may correspond to a second angle of the at least one side surface of the opening or the groove to the upper surface of the bank.

In one or more embodiments, the bank may have a opening or a groove, and at least one side surface of the opening or the groove may be inclined.

In one or more embodiments, the common voltage line may be disposed in the opening or the groove and extend along the at least one side surface of the opening or the groove, and at least a portion of the common voltage line may protrude beyond an upper surface of the bank and be electrically connected to the first common electrode and the second common electrode.

In one or more embodiments, a first angle of a portion of the common voltage line disposed on the at least one side surface of the opening or the groove to an upper surface of the planarization layer may correspond to a second angle of the at least one side surface of the opening or the groove to the upper surface of the planarization layer.

In one or more embodiments, the display device may further include an encapsulation layer disposed on the first common electrode, the second common electrode, and the metal pattern, and a plurality of touch metals disposed on the encapsulation layer. In one or more aspects, at least one of the plurality of touch metals may overlap with at least a portion of the common voltage line.

According to the one or more example embodiments described herein, a display device can be provided that includes a substrate including a display area where an image is displayed, a plurality of pixel electrodes disposed on the substrate, a common electrode disposed over the plurality of pixel electrodes, a bank disposed in a matrix form and overlapping with areas between the plurality of pixel electrodes, and a common voltage line disposed on the bank and disposed in the matrix form. In one or more aspects, at least a portion of the common electrode may extend on the bank and be electrically connected to the common voltage line.

In one or more embodiments, the bank may have a width greater than the common voltage line.

In one or more embodiments, the display device may further include an encapsulation layer disposed on the common electrode, and a plurality of touch metals disposed on the encapsulation layer. In one or more embodiments, at least one of the plurality of touch metals may overlap with at least a portion of the common voltage line.

In one or more embodiments, the display device may further include a spacer disposed on the bank and comprising a opening or a groove, and at least one side surface of the opening or the groove may be inclined. In one or more aspects, the common voltage line may be disposed in the opening or the groove and extend along the at least one side surface of the opening or the groove.

In one or more embodiments, the bank may have a opening or a groove, and at least one side surface of the opening or the groove may be inclined. In one or more embodiments, the common voltage line may be disposed in the opening or the groove and extend along the at least one side surface of the opening or the groove.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a substrate comprising a display area where an image is displayed and on which a plurality of subpixels are disposed;
a planarization layer on the substrate;
a first pixel electrode located in an area of a first subpixel among the plurality of subpixels and on the planarization layer, the first pixel electrode comprising a first edge and a second edge;
a second pixel electrode located in an area of a second subpixel among the plurality of subpixels and on the planarization layer, the second pixel electrode spaced apart from the first pixel electrode and comprising a third edge that is adjacent to the second edge and a fourth edge;
a bank on the second edge of the first pixel electrode and the third edge of the second pixel electrode;
a common voltage line on the bank, the common voltage line delivering a common voltage;
a first intermediate layer on the first pixel electrode, the first intermediate layer extending along a first side surface of the bank;
a second intermediate layer on the second pixel electrode, the second intermediate layer extending along a second side surface of the bank;
an organic layer on the bank, the organic layer spaced apart from the first intermediate layer and spaced from the second intermediate layer;
a first common electrode on the first intermediate layer, the first common electrode electrically connected to one side of the common voltage line;
a second common electrode on the second intermediate layer, the second common electrode electrically connected to another side of the common voltage line; and
a metal pattern on the organic layer, the metal pattern spaced apart from the first common electrode and spaced apart from the second common electrode.

2. The display device of claim 1, wherein the organic layer comprises an organic material that is included in the first intermediate layer and the second intermediate layer.

3. The display device of claim 1, wherein the metal pattern comprises a same metal as the first common electrode and the second common electrode and is in an electrically floating state.

4. The display device of claim 1, wherein the common voltage line comprises:
a lower metal line;
an intermediate metal line on the lower metal line; and
an upper metal line on the intermediate metal line, the upper metal line comprising:
a first protrusion protruding beyond an edge of one side of the intermediate metal line; and
a second protrusion protruding beyond an edge of another side of the intermediate metal line.

5. The display device of claim 4, wherein the first common electrode contacts at least one of the first protrusion and a side portion of the intermediate metal line, and the second common electrode contacts at least one of the second protrusion and a side portion of the intermediate metal line.

6. The display device of claim 1, wherein the common voltage line has a mesh form in the display area.

7. The display device of claim 1, wherein at least one of the organic layer and the metal pattern has a mesh form in the display area.

8. The display device of claim 1, wherein a size of a lower surface of the common voltage line is less than a size of an upper surface of the bank and the upper surface of the bank is flat.

9. The display device of claim 1, further comprising:
a spacer on the bank, the spacer comprising a opening or a groove,
wherein at least one side surface of the opening or the groove is inclined.

10. The display device of claim 9, wherein the common voltage line is in the opening or the groove and extends along the at least one side surface of the opening or the groove, and at least a portion of the common voltage line protrudes beyond an upper surface of the spacer and is electrically connected to the first common electrode and the second common electrode.

11. The display device of claim 10, wherein a first angle of a portion of the common voltage line disposed on the at least one side surface of the opening or the groove to an upper surface of the bank corresponds to a second angle of the at least one side surface of the opening or the groove to the upper surface of the bank.

12. The display device of claim 1, wherein the bank has a opening or a groove and at least one side surface of the opening or the groove is inclined.

13. The display device of claim 12, wherein the common voltage line is in the opening or the groove and extends along the at least one side surface of the opening or the groove, and at least a portion of the common voltage line protrudes beyond an upper surface of the bank and is electrically connected to the first common electrode and the second common electrode.

14. The display device of claim 13, wherein a first angle of a portion of the common voltage line disposed on the at least one side surface of the opening or the groove to an upper surface of the planarization layer corresponds to a second angle of the at least one side surface of the opening or the groove to the upper surface of the planarization layer.

15. The display device of claim 1, further comprising:
an encapsulation layer on the first common electrode, the second common electrode, and the metal pattern; and
a plurality of touch metals on the encapsulation layer,
wherein at least one of the plurality of touch metals overlaps with at least a portion of the common voltage line.

16. A display device comprising:
a substrate comprising a display area where an image is displayed;
a plurality of pixel electrodes on the substrate;
a common electrode over the plurality of pixel electrodes;
a bank having a matrix form, the bank overlapping with areas between the plurality of pixel electrodes; and
a common voltage line on the bank, the common voltage line having the matrix form, wherein at least a portion of the common electrode extends on the bank and is electrically connected to the common voltage line.

17. The display device of claim 16, wherein the bank has a width that is greater than a width of the common voltage line.

18. The display device of claim 16, further comprising:
an encapsulation layer on the common electrode; and
a plurality of touch metals on the encapsulation layer,
wherein at least one of the plurality of touch metals overlaps with at least a portion of the common voltage line.

19. The display device of claim 16, further comprising:
a spacer on the bank, the spacer comprising a opening or a groove,
wherein at least one side surface of the opening or the groove is inclined, and the common voltage line is in the opening or the groove and extends along the at least one side surface of the opening or the groove.

20. The display device of claim 16, wherein the bank has a opening or a groove and at least one side surface of the opening or the groove is inclined, and the common voltage line is in the opening or the groove and extends along the at least one side surface of the opening or the groove.
